(19) United States
(12) Patent Application Publication
(10) Pub. No.: US 2025/0176383 A1
(43) Pub. Date: May 29, 2025

(54) DISPLAY PANEL, DISPLAY METHOD AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Fei FANG, Beijing (CN); Zhisong ZHANG, Beijing (CN); Yangzhong JING, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/859,584

(22) PCT Filed: Nov. 16, 2023
(86) PCT No.: PCT/CN2023/132014

§ 371 Date: Oct. 24, 2024

(30) Foreign Application Priority Data
Dec. 1, 2022 (CN) 202211538257.3

(51) Int. Cl. H10K 59/131; H10K 59/12; H10K 59/122

(52) U.S. Cl. CPC H10K 59/131; H10K 59/1201; H10K 59/122

(57) ABSTRACT

In a display panel, extension parts on a connection line with which a signal line in an n^{th} row of sub-pixel areas is connected extend to other rows of sub-pixel areas except the n^{th} row of sub-pixel areas. In such a structure, when light-emitting devices in the n^{th} row of sub-pixel areas are driven, the extension parts in a winding structure with which a signal line in the n^{th} row of sub-pixel areas is connected are disposed in other rows of sub-pixel areas and do not affect pixel driving circuits in the n^{th} row of sub-pixel areas and because pixel driving circuits in other rows of sub-pixel areas are not in a data writing state at this time, a voltage change on the extension parts has little influence on the pixel driving circuits in other rows of sub-pixel areas.

### CROSS-REFERENCE TO RELATED APPLICATION

The present disclosure is a US national stage of international application No. PCT/CN2023/132014, filed on Nov. 16, 2023, which claims priority to Chinese Patent Application No. 202211538257.3, filed on Dec. 1, 2022 and entitled “DISPLAY PANEL, DISPLAY METHOD AND DISPLAY APPARATUS”, the disclosures of which are incorporated herein by reference in their entireties.

### TECHNICAL FIELD

The present disclosure relates to the field of display technologies, in particular to a display panel, a display method and a display apparatus.

### BACKGROUND

Display panels are devices capable of realizing a display function.

One type of display panels includes a conventional display area and a light-transmitting display area. A plurality of light-emitting devices are arranged in both the conventional display area and the light-transmitting display area, so that both the conventional display area and the light-transmitting display area can display pictures.

However, there may be a problem of uneven brightness in areas in the above conventional display area close to the light-transmitting display area, resulting in a poorer display effect of the display panel.

### SUMMARY

Embodiments of the present disclosure provide a display panel, a display method and a display apparatus. The technical solution is as follows:

According to one aspect of the embodiments of the present disclosure, a display panel is provided. The display panel includes: a substrate having a light-transmitting display area and a conventional display area surrounding the light-transmitting display area thereon, where the light-transmitting display area and the conventional display area have a plurality of sub-pixel areas therein, the plurality of sub-pixel areas are arranged in a plurality of rows of sub-pixel areas on the substrate, and the plurality of sub-pixel areas have connected pixel driving circuits and light-emitting devices therein;
the conventional display area includes a winding pattern and a plurality of conventional signal lines respectively disposed in the plurality of rows of sub-pixel areas, and the winding pattern and the plurality of conventional signal lines are disposed in different layers; and
the winding pattern includes a plurality of connection lines respectively disposed in the plurality of rows of sub-pixel areas, each of the plurality of connection lines includes a main line extending along a row direction of the sub-pixel area and a plurality of extension parts extending to adjacent sub-pixel areas, each of the plurality of connection lines is connected with the plurality of conventional signal lines, and the plurality of extension parts on each of the plurality of connection lines with which each of the plurality of conventional signal lines in an n^{th} row of sub-pixels is connected extend to other rows of sub-pixel areas except the n^{th} row of sub-pixels, wherein n is an integer greater than zero.

Optionally, the display panel further includes a pixel definition layer disposed on the substrate, the pixel definition layer includes a shielding area and a plurality of opening areas, the plurality of opening areas are respectively disposed in the plurality of sub-pixel areas, and an orthographic projection of each of the plurality of extension parts on the substrate is disposed in an orthographic projection of the shielding area on the substrate; and
the plurality of extension parts includes at least one disconnected extension part, and the disconnected extension part is disconnected from the main line.

Optionally, each of the plurality of extension parts includes at least one sub-line segment, and the at least one sub-line segment is arranged around the opening area.

Optionally, each of the plurality of extension parts includes two sub-segments respectively disposed on two sides of the opening area in the row direction.

Optionally, the display panel further includes a power line, and the at least one disconnected extension part is electrically connected with the power line.

Optionally, the pixel driving circuit includes a storage capacitor disposed in the sub-pixel area, and a node connection line, the node connection line is connected with one end of the storage capacitor, and the capacitor connection has an N1 node;
a conventional signal line in the n^{th} row of sub-pixel areas is connected with a connection line of a winding structure corresponding to the n^{th} row of sub-pixel areas; and
a main line of the connection line of the winding structure corresponding to the n^{th} row of sub-pixel areas is disposed on a first side of the N1 nodes of the n^{th} row of sub-pixel areas, extension parts of the connection line of the winding structure corresponding to the n^{th} row of sub-pixel areas extend to an adjacent row of sub-pixel areas on a second side of the n^{th} row of sub-pixel areas, and the first side and the second side are both sides in a direction perpendicular to the row direction.

Optionally, a conventional signal line in the n^{th} row of sub-pixel areas is connected with connection lines of the winding structures corresponding to other rows of sub-pixel areas except the n^{th} row of sub-pixel areas in the plurality of rows of sub-pixel areas.

Optionally, the display panel further includes a jumper line, one end of the jumper line is connected with the conventional signal line in the n^{th} row of sub-pixel areas, and the other end of the jumper line is connected with the connection lines of the winding structures corresponding to other rows of sub-pixel areas except the n^{th} row of sub-pixel areas.

Optionally, the jumper line and the winding structure are of a same layer structure.

Optionally, the conventional signal line in the n^{th} row of sub-pixel areas is connected with a connection line of a winding structure corresponding to an (n+x)^{th} row of sub-pixel areas in the plurality of rows of sub-pixel areas, and x is an integer greater than zero.

Optionally, the conventional signal line in the n^{th} row of sub-pixel areas is connected with a connection line of a winding structure corresponding to an (n−x)^{th} row of sub-pixel areas in the plurality of rows of sub-pixel areas, and x is an integer greater than zero.

Optionally, the winding pattern further includes a plurality of surrounding lines extending around the light-transmitting display area, and an end part of each of the plurality of surrounding lines is connected with each of the plurality of connection lines.

Optionally, the conventional signal line includes a gate line, and each of the plurality of connection lines is connected with the gate line.

Optionally, the display panel includes a source and drain metal pattern, and the winding pattern and the source and drain metal pattern are of a same layer structure.

Optionally, light-emitting devices in the light-transmitting display area are connected with the pixel driving circuits in one-to-one correspondence.

Optionally, one pixel driving circuit in the light-transmitting display area is connected with at least two light-emitting devices.

Optionally, a density of light-emitting devices in the light-transmitting display area is less than a density of light-emitting devices in the conventional display area.

According to another aspect of the present disclosure, a display panel is provided. The display panel includes: a light-transmitting display area and a conventional display area surrounding the light-transmitting display area; wherein
the light-transmitting display area and the conventional display area have a plurality of sub-pixel areas therein, the plurality of sub-pixel areas are arranged in a plurality of rows of sub-pixel areas, and the sub-pixel areas have connected pixel driving circuits and light-emitting devices therein;
the conventional display area includes a winding pattern, the light-transmitting display area includes a plurality of light-transmitting area signal lines, and the plurality of light-transmitting area signal lines and the winding pattern are disposed in different layers; and
the winding pattern includes a plurality of winding structures respectively corresponding to the plurality of rows of sub-pixel areas, a winding structure corresponding to an n^{th} row of sub-pixel areas in the plurality of rows of sub-pixel areas includes a surrounding line extending around the light-transmitting display area and a connection line disposed in the n^{th} row of sub-pixels, the connection line is connected with an end part of the surrounding line, the connection line includes a main line extending along a row direction of the n^{th} row of sub-pixel areas and a plurality of extension parts extending to the sub-pixel areas, connection lines of the plurality of winding structures are respectively connected with the plurality of light-transmitting area signal lines, extension parts on a connection line with which the light-transmitting area signal line in the n^{th} row of sub-pixels is connected extend to other rows of sub-pixel areas except the n^{th} row of sub-pixels, and n is an integer greater than zero.

According to another aspect of the present disclosure, a display apparatus is provided. The display apparatus includes an optical device and the above display panel, wherein the optical device is disposed on a back surface of the display panel, and there is an overlapping area between an orthogonal projection of the optical device on the display panel and the light-transmitting display area of the display panel.

According to another aspect of the present disclosure, a display method for a display panel is provided. The display method for a display panel is used for controlling the above display panel and includes:
when driving the light-emitting devices in the n^{th} row of sub-pixel areas, loading a first potential to the conventional signal line in the n^{th} row of sub-pixel areas at a first moment, so as to charge the pixel driving circuits in the n^{th} row of sub-pixel areas, and cause at least part of circuits of the pixel driving circuits in sub-pixel areas where the extension parts are disposed to jump to the first potential under an influence of the first potential, the sub-pixel areas where the extension parts are disposed being sub-pixel areas in the plurality of rows of sub-pixel areas in the display panel except the n^{th} row of sub-pixel areas; and
loading a second potential to the conventional signal line in the n^{th} row of sub-pixel areas at a second moment, so as to stop charging the pixel driving circuits in the n^{th} row of sub-pixel areas, and cause at least part of circuits of the pixel driving circuits in the sub-pixel areas where the extension parts are disposed to jump to the second potential under the influence of the second potential.

According to another aspect of the embodiments of the present disclosure, a control apparatus for a display panel is provided. The control apparatus for a display panel is configured to control the above display panel, and includes:
a first control component, configured to, when driving the light-emitting devices in the n^{th} row of sub-pixel areas, load a first potential to the conventional signal line in the n^{th} row of sub-pixel areas at a first moment, so as to charge the pixel driving circuits in the n^{th} row of sub-pixel areas, and cause at least part of circuits of the pixel driving circuits in the sub-pixel areas where the extension parts are disposed to jump to the first potential under the influence of the first potential, the sub-pixel areas where the extension parts are disposed being the sub-pixel areas in the plurality of rows of sub-pixel areas in the display panel except the n^{th} row of sub-pixel areas; and
a second control component, configured to load a second potential to the conventional signal line in the n^{th} row of sub-pixel areas at a second moment, so as to stop charging the pixel driving circuits in the n^{th} row of sub-pixel areas, and cause at least part of circuits of the pixel driving circuits in the sub-pixel areas where the extension parts are disposed to jump to the second potential under the influence of the second potential.

According to another aspect of the embodiments of the present disclosure, a computer storage medium is provided. The computer storage medium has at least one instruction, at least one program, a code set or an instruction set stored therein, and the at least one instruction, the at least one program, the code set or the instruction set is loaded and executed by a processor to implement the above display method for a display panel.

According to another aspect of the embodiments of the present disclosure, a computer program product or computer program is provided. The computer program product or computer program includes computer instructions stored in a computer-readable storage medium. A processor of a computer device reads the computer instructions from the computer-readable storage medium, and the processor executes the computer instructions, so that the computer device executes the above methods according to various optional embodiments.

The technical solutions according to the embodiments of the present disclosure at least have the following beneficial effects:
the extension parts on the connection line with which the signal line in the n^{th} row of sub-pixel areas is connected extend to other rows of sub-pixel areas except the n^{th} row of sub-pixel areas, In such a structure, when the light-emitting devices in the n^{th} row of sub-pixel areas are driven, the extension parts in the winding structure connected with the signal line in the n^{th} row of sub-pixel areas are disposed in other rows of sub-pixel areas, and do not affect the pixel driving circuits in the n^{th} row of sub-pixel areas and because the pixel driving circuits in other rows of sub-pixel areas are not in a data writing state at this time, a voltage change on the extension parts has little influence on the pixel driving circuits in other rows of sub-pixel areas, thereby improving a display effect of the display panel, and the reducing possibility of generating the problem of uneven brightness.

### BRIEF DESCRIPTION OF DRAWINGS

To describe the technical solutions in the embodiments of the present disclosure more clearly, the following briefly introduces the accompanying drawings required for describing the embodiments. Apparently, the accompanying drawings in the following descriptions show merely some embodiments of the present disclosure, and a person of ordinary skill in the art may still derive other drawings from these accompanying drawings without creative efforts.

FIG. 1 is a schematic structural diagram of a display panel;

FIG. 2 is an enlarged schematic structural diagram of the display panel shown in FIG. 1;

FIG. 3 is a schematic diagram of vision of the display panel shown in FIG. 1;

FIG. 4 is a schematic potential diagram of the display panel shown in FIG. 1;

FIG. 5 is a schematic structural diagram of a display panel according to an embodiment of the present disclosure;

FIG. 6 is a partially enlarged schematic structural diagram of the display panel shown in FIG. 5;

FIG. 7 is a sectional schematic structural diagram of the display panel shown in FIG. 6;

FIG. 8 shows a circuit structural diagram of a pixel driving circuit;

FIG. 9 is a layout of part of the structure in a display panel according to an embodiment of the present disclosure;

FIG. 10 is a disassembled and merged layout of part of the area in the display panel shown in FIG. 9;

FIG. 11 is a schematic structural diagram of another display panel according to an embodiment of the present disclosure;

FIG. 12 is a layout corresponding to part of the structure in the display panel shown in FIG. 11;

FIG. 13 is a schematic structural diagram of another display panel according to an embodiment of the present disclosure;

FIG. 14 is a layout corresponding to the display panel shown in FIG. 13;

FIG. 15 is a schematic structural diagram of another display panel according to an embodiment of the present disclosure;

FIG. 16 is a structural layout of another display panel according to an embodiment of the present disclosure;

FIG. 17 is a flowchart of a display method for a display panel according to an embodiment of the present disclosure; and

FIG. 18 is a block diagram of a control apparatus for a display panel according to an embodiment of the present disclosure.

Through the above accompanying drawings, clear embodiments of the present disclosure have been shown, and will be described in more detail hereinafter. These accompanying drawings and written descriptions are not intended to limit the scope of the concept of the present disclosure in any way, but to explain the concept of the present disclosure to those skilled in the art by referring to specific embodiments.

### DETAILED DESCRIPTION

For clearer descriptions of the objectives, technical solutions, and advantages of the present disclosure, embodiments of the present disclosure are described in further detail hereinafter with reference to the accompanying drawings.

At present, in order to improve the screen ratio of a display apparatus, a display panel in the display apparatus may be designed as a partially light-transmitting display panel. The orthogonal projection of a photosensitive surface of an optical device in the display apparatus on the display panel may be disposed in the partially light-transmitting area, and the optical device in the display apparatus is disposed on one side opposite to a display surface of the display panel.

The display panel of such a structure has a light-transmitting display area and a conventional display area. The light-transmitting display area may also be called a full display with camera (FDC) area. A plurality of light-emitting devices are arranged in both the conventional display area and the light-transmitting display area, so that both the conventional display area and the light-transmitting display area can display pictures.

The plurality of light-emitting devices disposed in the light-transmitting display area are coupled with part of pixel driving circuits in a plurality of pixel driving circuits disposed in the conventional display area on both sides of the light-transmitting display area in one-to-one correspondence, and such part of pixel driving circuits are configured to control picture display of the light-transmitting display area.

The plurality of light-emitting devices disposed in the light-transmitting display area may be connected with the plurality of pixel driving circuits in the corresponding conventional display area through a plurality of connection lines, and a part of each of the plurality of connection lines is disposed in the light-transmitting display area and the other part is disposed in the conventional display area.

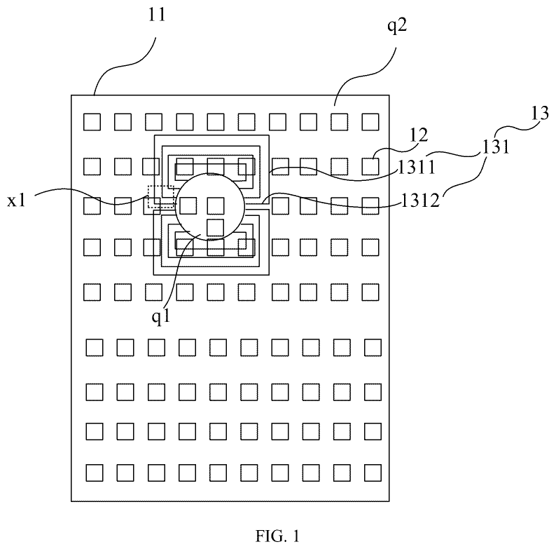

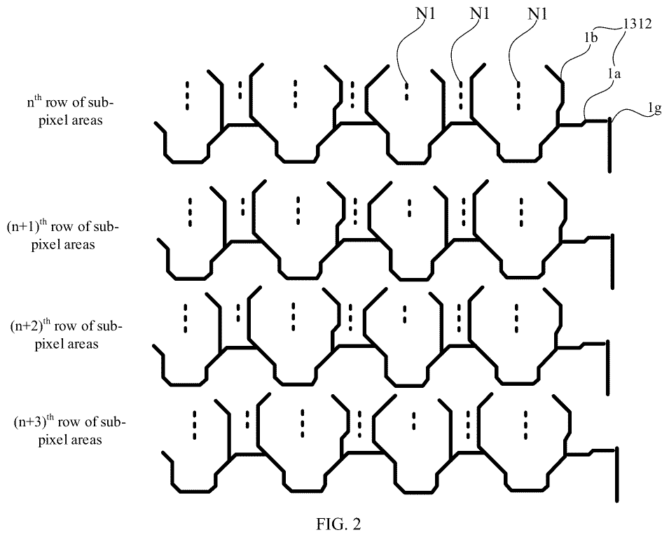

As shown in FIG. 1, FIG. 1 is a schematic structural diagram of a display panel, and FIG. 2 is an enlarged schematic structural diagram of the display panel shown in FIG. 1 (FIG. 2 may be an enlarged schematic structural diagram of a dotted box x1 in FIG. 1). Please refer to FIG. 1 and FIG. 2. A display panel 11 includes a light-transmitting display area q1 and a conventional display area q2 surrounding the light-transmitting display area. The light-transmitting display area q1 and the conventional display area q2 have a plurality of sub-pixel areas therein, and the plurality of sub-pixel areas are arranged in a plurality of rows of sub-pixel areas.

The display panel also includes pixel driving circuits 12 and a winding pattern 13, the pixel driving circuits 12 and the winding pattern 13 are disposed in the conventional display area q2, and the winding pattern 13 includes a plurality of winding structures 131 corresponding to the plurality of rows of sub-pixel areas.

The winding structure 131 corresponding to a n^{th} row of sub-pixel areas in the plurality of rows of sub-pixel areas includes a surrounding line 1311 extending around the light-transmitting display area q1 and a connection line 1312 disposed in the n^{th} row of sub-pixel areas. The connection line 1312 is connected with the surrounding line 1311 and includes a main line 1a extending along a row direction f1 of the n^{th} row of sub-pixels and a plurality of extension parts 1b extending to the sub-pixel areas. The light-transmitting display area q1 has a plurality of light-transmitting area gate lines 1g disposed in the plurality of rows of sub-pixel areas, each connection line 1312 of the plurality of winding structures 131 is connected with each of the plurality of light-transmitting area gate lines 1g, and the extension parts 1b on the connection line 1312 connected with the light-transmitting area gate line 1g in the n^{th} row of sub-pixel areas extend into the n^{th} row of sub-pixel areas.

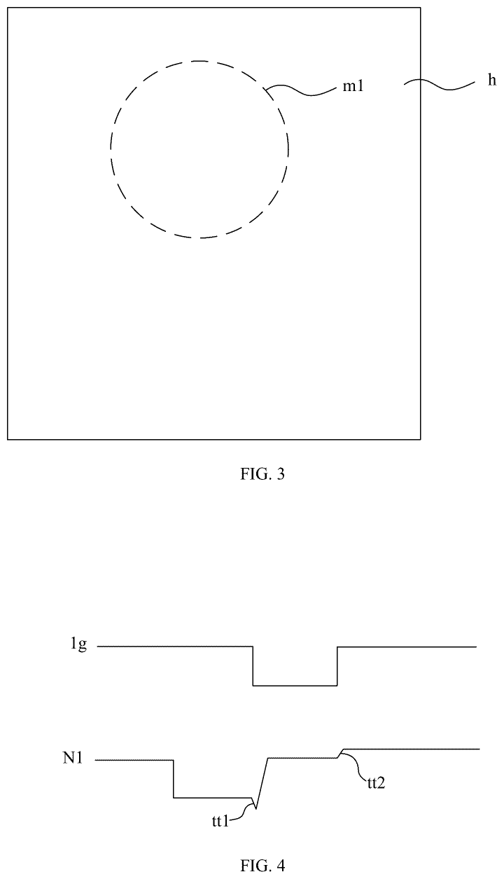

The pixel driving circuit in each sub-pixel area may have a storage capacitor, one end of the storage capacitor is connected with an N1 node in the pixel driving circuit, and the N1 node is easily interfered by other circuit structures. As can be seen from FIG. 2, a distance between the N1 node and the extension part 1b in some sub-pixel areas is too close, which in turn causes a potential of the N1 nodes to be affected by the extension parts 1b, resulting in the brightness of this part of sub-pixel areas to be uneven with that of other areas. Exemplarily, as shown in FIG. 3, FIG. 3 is a schematic diagram of vision of the display panel shown in FIG. 1, and FIG. 4 is a schematic diagram of a potential of the display panel shown in FIG. 1. As can be seen from FIG. 4, in the n^{th} row of sub-pixel areas, the potential of the N1 node will jump at tt1 and tt2 by the influence of the gate line 1g, thereby affecting normal light emission of light-emitting units in areas nearby the light-transmitting display area. Please refer to FIG. 3, FIG. 3 may be a schematic diagram of the display panel displaying a solid color picture h, in which the edge of the light-transmitting display area q has a circle of marks m1 of uneven brightness, and such a problem may be called a circular uneven brightness (Mura) problem.

The embodiments of the present disclosure provide a display panel, a display method and a display apparatus, which can solve the problem existing in the related art.

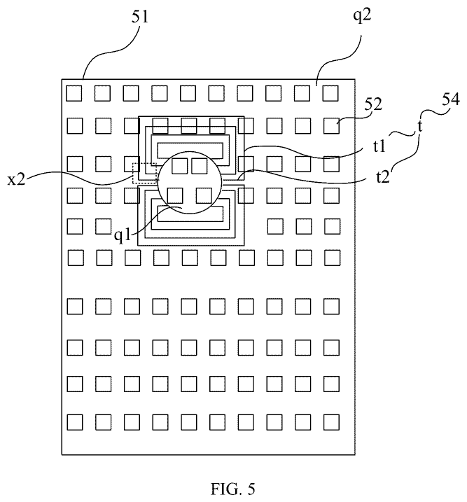

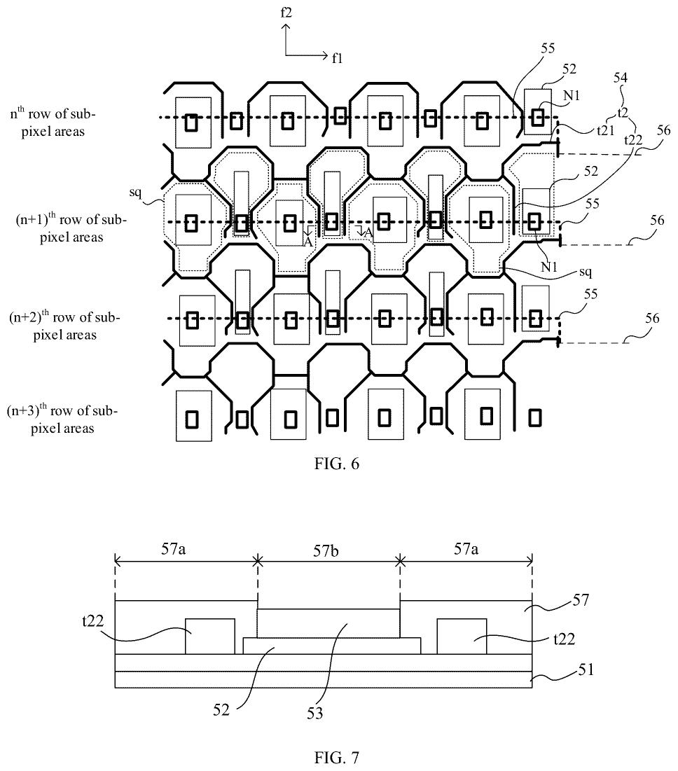

FIG. 5 is a schematic structural diagram of a display panel according to an embodiment of the present disclosure, FIG. 6 is a partial enlarged schematic structural diagram of the display panel shown in FIG. 5 (FIG. 6 is an enlarged schematic structural diagram at a dotted box x2 in FIG. 5), and FIG. 7 is a sectional schematic structural diagram of the display panel shown in FIG. 6 (the sectional position may be at A-A). Please refer to FIGS. 5, 6 and 7, the display panel includes a substrate 51.

The substrate 51 has a light-transmitting display area q1 and a conventional display area q2 surrounding the light-transmitting display area thereon. The light-transmitting display area q1 and the conventional display area q2 have a plurality of sub-pixel areas sq therein, the plurality of sub-pixel areas sq are arranged in a plurality of rows of sub-pixel areas on the substrate, and the sub-pixel areas sq have connected pixel driving circuits 52 and light-emitting devices 53 therein. FIG. 6 shows a plurality of sub-pixel areas sq in one row of sub-pixel areas, and other rows of sub-pixel areas may be divided in a way that refers to this row of sub-pixel areas.

The conventional display area q2 includes a wiring pattern 54 and a plurality of conventional signal lines 55 respectively disposed in the plurality of rows of sub-pixel areas, and the wiring pattern 54 and the conventional signal lines 55 are disposed in different layers.

The winding pattern 54 includes a plurality of connection lines t2 respectively disposed in the plurality of rows of sub-pixels, and the connection line t2 includes a main line t21 extending along a row direction f1 of the sub-pixel area and a plurality of extension parts t22 extending to adjacent sub-pixel areas. The connection line t2 is connected with the conventional signal line 55. The extension parts t22 on the connection line t2 connected with the conventional signal line 55 in the n^{th} row of sub-pixels extend to other rows of sub-pixel areas except the n^{th} row of sub-pixels, and n is an integer greater than zero. In the embodiment of the present disclosure, the light-emitting device may include an organic light-emitting diode, or other devices capable for electroluminescence.

In summary, for the display panel according to the embodiment of the present disclosure, the extension parts on the connection line with which the signal line in the n^{th} row of sub-pixel areas is connected extend to other rows of sub-pixel areas except the n^{th} row of sub-pixel areas. In such a structure, when the light-emitting devices in the n^{th} row of sub-pixel areas are driven, the extension parts in the winding structure with which the signal line in the n^{th} row of sub-pixel areas is connected are disposed in other rows of sub-pixel areas and do not affect the pixel driving circuits in the n^{th} row of sub-pixel areas and because the pixel driving circuits in other rows of sub-pixel areas are not in a data writing state at this time, a voltage change on the extension parts has little influence on the pixel driving circuits in other rows of sub-pixel areas, thereby improving a display effect of the display panel and reducing the possibility of generating the problem of uneven brightness.

The winding pattern 54 further includes a plurality of surrounding lines t1 extending around the light-transmitting display area q1, and end parts of the surrounding lines t1 are connected with the connection lines t2. One surrounding line t1 and a connection line t2 with which the surrounding line t1 is connected may form one winding structure t. In addition, the conventional signal line includes a conventional gate line, and the connection line t2 may be connected with the conventional gate line.

In addition, in the display panel according to the embodiment of the present disclosure, other areas except the area where the winding pattern 54 is disposed may also have patterns (which may be called dummy patterns, and the dummy patterns may be connected with a power line) on the same layer as the winding pattern 54, which is not limited by the embodiment of the present disclosure.

In another optional embodiment, please refer to FIG. 5. The display panel includes a light-transmitting display area q1 and a conventional display area q2 surrounding the light-transmitting display area q1.

The light-transmitting display area q1 and the conventional display area q2 have a plurality of sub-pixel areas sq therein, the plurality of sub-pixel areas sq are arranged in a plurality of rows of sub-pixel areas, and the sub-pixel areas sq have connected pixel driving circuits 52 and light-emitting devices 53 therein.

The conventional display area q2 includes a winding pattern 54 therein, the light-transmitting display area q1 includes a plurality of light-transmitting area signal lines 56, and the light-transmitting area signal lines 56 and the winding pattern 54 are disposed in different layers.

The winding pattern 54 includes a plurality of winding structures t respectively corresponding to the plurality of rows of sub-pixel areas. The winding structure t corresponding to the n^{th} row of sub-pixel areas in the plurality of rows of sub-pixel areas includes a surrounding line t1 extending around the light-transmitting display area q1 and a connection line t2 disposed in the n^{th} row of sub-pixels, and the connection line t2 is connected with an end part of the surrounding line t1. The connection line t2 includes a main line t21 extending along the row direction f1 of the n^{th} row of sub-pixel areas and a plurality of extension parts t22 extending to the sub-pixel areas. The connection lines t2 of the plurality of winding structures t are respectively connected with the plurality of light-transmitting area signal lines 56, and the extension parts t22 on the connection line t2 with which the light-transmitting area signal line 56 in the n^{th} row of sub-pixels is connected extend to other rows of sub-pixel areas except the n^{th} row of sub-pixels, where n is an integer greater than zero.

In summary, for the display panel according to the embodiment of the present disclosure, the extension parts on the connection line with which the signal line in the n^{th} row of sub-pixel areas is connected extend to other rows of sub-pixel areas except the n^{th} row of sub-pixel areas. In such a structure, when the light-emitting devices in the n^{th} row of sub-pixel areas are driven, the extension parts in the winding structure with which the signal line in the n^{th} row of sub-pixel areas is connected are disposed in other rows of sub-pixel areas and do not affect the pixel driving circuits in the n^{th} row of sub-pixel areas and because the pixel driving circuits in other rows of sub-pixel areas are not in a data writing state at this time, a voltage change on the extension parts has little influence on the pixel driving circuits in other rows of sub-pixel areas, thereby improving a display effect of the display panel and reducing the possibility of generating the problem of uneven brightness.

Please refer to FIG. 7, the display panel further includes a pixel definition layer 57 disposed on the substrate 51, the pixel definition layer 57 includes a shielding area 57a and a plurality of opening areas 57b respectively disposed in the plurality of sub-pixel areas, and an orthographic projection of the extension part t22 on the substrate 51 is disposed in an orthographic projection of the shielding area 57a on the substrate 51. That is, the extension part t22 may not affect an aperture ratio of the display panel.

In the embodiment of the present disclosure, the conventional signal line 55 may be a gate line or other signal lines in the conventional display area, and the light-transmitting area signal line 56 may be a gate line or other signals line in the light-transmitting display area.

In an exemplary embodiment, in the display panel according to the embodiment of the present disclosure, the light-emitting devices in the light-transmitting display area are connected with the pixel driving circuits in one-to-one correspondence, that is, one pixel driving circuit drives one light-emitting device. Or, the pixel driving circuit in the light-transmitting display area is connected with at least two light-emitting devices, that is, one pixel driving circuit may drive a plurality of light-emitting devices. In addition, a density of the light-emitting devices in the light-transmitting display area may be less than a density of the light-emitting devices in the conventional display area, so that light transmittance in the light-transmitting display area can be improved.

In the embodiment of the present disclosure, there are at least two modes to realize that the extension parts t22 on the connection line t2 with which the signal line in the n^{th} row of sub-pixel areas is connected extend to other rows of sub-pixel areas except the n^{th} row of sub-pixel areas, which are explained respectively below.

For the first mode, please refer to FIG. 6. The pixel driving circuit 52 includes a storage capacitor disposed in the sub-pixel area and an N1 node (the position of N1 is indicated in the figure) connected with one end of the storage capacitor.

The conventional signal line 55 in the n^{th} row of sub-pixel areas is connected with the connection line t2 of the winding structure t corresponding to the n^{th} row of sub-pixel areas.

The main line t21 of the connection line t2 of the winding structure t corresponding to the n^{th} row of sub-pixel areas is disposed on a first side of the N1 nodes of the n^{th} row of sub-pixel areas, the extension parts t22 of the connection line t2 of the winding structure t corresponding to the n^{th} row of sub-pixel areas extend to an adjacent row of sub-pixel areas on a second side of the n^{th} row of sub-pixel areas, and the first side and the second side are both sides in a direction f2 perpendicular to the row direction f1. In the structure shown in FIG. 6, the first side is the upper side and the second side is the lower side.

As can be seen from FIG. 6, the main line t21 of the connection line t2 in the n^{th} row of sub-pixel areas is disposed in the n^{th} row of sub-pixel areas, but the extension parts t22 in the connection line t2 extend into the (n+1)^{th} row of sub-pixel areas. In such a structure, the extension parts t22 are farther away from the N1 nodes in the n^{th} row of sub-pixel areas, and do not affect the potential of the N1 nodes in the n^{th} row of sub-pixel areas, that is, the influence of an electric signal of the signal line in the n^{th} row of sub-pixel areas on the potential of the N1 nodes in the n^{th} row of sub-pixel areas is avoided, and the possibility of generating the mura problem nearby the FDC area is reduced.

FIG. 6 shows a case where the main line t21 of the connection line t2 of the winding structure t corresponding to the n^{th} row of sub-pixel areas is disposed on the upper side of the N1 nodes of the n^{th} row of sub-pixel areas, and the extension parts t22 of the connection line t2 of the winding structure t corresponding to the n^{th} row of sub-pixel areas extend to the adjacent row of sub-pixel areas on the lower side of the n^{th} row of sub-pixel areas. However, the main line t21 of the connection line t2 of the winding structure t corresponding to the n^{th} row of sub-pixel areas may also be disposed on the lower side of the N1 nodes of the n^{th} row of sub-pixel areas, and the extension parts t22 of the connection line t2 of the winding structure t corresponding to the n^{th} row of sub-pixel areas may also extend to an adjacent row of sub-pixel areas on the upper side of the n^{th} row of sub-pixel areas, which is not limited by the embodiment of the present disclosure.

It should be noted that in the display panel according to the embodiment of the present disclosure, the sub-pixel areas may be arranged in rows and columns, for example, in a plurality of rows and a plurality of columns, and each row of sub-pixel areas may include a plurality of sub-pixel areas arranged along the row direction. As shown in FIG. 6, the area between two adjacent main lines t21 may be a row of sub-pixel areas. Of course, the sub-pixel areas may also be divided in other ways, which is not limited by the embodiment of the present disclosure.

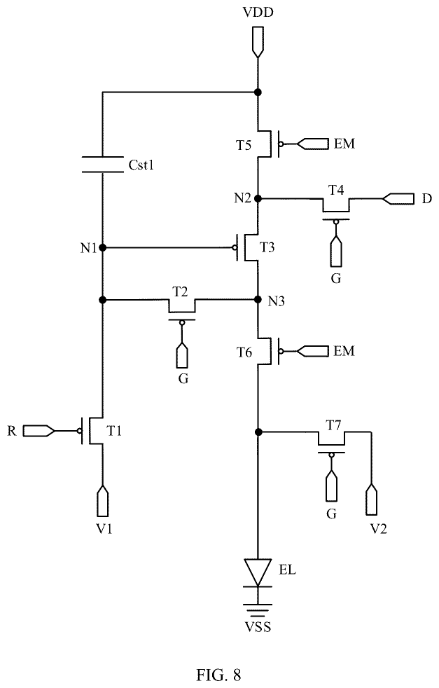

Please refer to FIG. 8, which shows a circuit structural diagram of a pixel driving circuit. The pixel driving circuit is a 7T1C structure, and the structure may include seven thin film transistors (TFTs), where a gate electrode of a third thin film transistor T3 is connected with a first node N1, a source electrode of the third thin film transistor T3 is connected with a second node N2, and a drain electrode of the third thin film transistor T3 is connected with a third node N3.

A gate electrode of a fourth thin film transistor T4 is connected with a gate line G, a source electrode of the fourth thin film transistor T4 is connected with a data signal line D, and a drain electrode of the fourth thin film transistor T4 is connected with the second node N2.

A gate electrode of a second thin film transistor T2 is connected with the gate line G, a source electrode of the second thin film transistor T2 is connected with the third node N3, and a drain electrode of the second thin film transistor T2 is connected with the first node N1.

A gate electrode of a first thin film transistor T1 is connected with a reset signal line R, a drain electrode of the first thin film transistor T1 is connected with a first reference signal line V1, and a source electrode of the first thin film transistor T1 is connected with the first node N1.

A gate electrode of a fifth thin film transistor T5 and a gate electrode of a sixth thin film transistor T6 are connected with a light-emitting signal line EM, a source electrode of the fifth thin film transistor T5 is connected with a constant voltage high potential VDD, a drain electrode of the fifth thin film transistor T5 is connected with the second node N2, a source electrode of the sixth thin film transistor T6 is connected with the third node N3, a drain electrode of the sixth thin film transistor T6 is connected with an anode of a light-emitting device EL, and a cathode of a light-emitting device EL is connected with a low potential VSS.

A gate electrode of a seventh thin film transistor T7 is connected with the gate line G, a drain electrode of the seventh thin film transistor T7 is connected with a second reference signal line V2, and a source electrode of the seventh thin film transistor T7 is connected with the anode of the light-emitting device EL.

One end of a storage capacitor Cst1 may be connected with the first node N1, and the other end of the storage capacitor Cst1 may be connected with the constant voltage high potential VDD.

The N1 node is easily influenced by a potential change of other structures, which further leads to a brightness change of a light-emitting unit driven by the pixel driving circuit.

Of course, the pixel driving circuit in the display panel according to the embodiment of the present disclosure may also have other structures, which is not limited by the embodiment of the present disclosure.

In the first mode, the conventional signal line 55 in the n^{th} row of sub-pixel areas is connected with the connection line t2 of the winding structure t corresponding to the same row of sub-pixel areas, and the extension parts t22 extend to an adjacent row of sub-pixel areas to prevent the extension parts t22 from affecting the N1 nodes in the present row of sub-pixel areas.

Specifically, in a case that the conventional signal line 55 is a gate line, when driving the light-emitting devices in the n^{th} row of sub-pixel areas, a control component may load a first potential to the gate line in the n^{th} row of sub-pixel areas at a first moment, so as to charge the pixel driving circuits in the n^{th} row of sub-pixel areas, and the N1 nodes of the pixel driving circuits in the (n+1)^{th} row of sub-pixel areas where the extension parts are disposed jump to the first potential under the influence of the first potential.

At a second moment, a second potential is loaded to the gate line in the n^{th} row of sub-pixel areas to stop charging the pixel driving circuits in the n^{th} row of sub-pixel areas, and the N1 nodes of the pixel driving circuits in the (n+1)^{th} row of sub-pixel areas where the extension parts are disposed jump to the second potential under the influence of the second potential. One of the first potential and the second potential is a high potential, and the other potential is a low potential.

In the above driving process, the (n+1)^{th} row of sub-pixel areas are in a light-emitting state, but not in a charging state, the potential of the N1 nodes jumps to the first potential and then to the second potential in a very short time, and two jumping processes counteract each other out, so that the brightness of the light-emitting devices in the (n+1)^{th} row of sub-pixel areas is basically not affected. In this way, the possibility of annular mura nearby the FDC area is avoided, and the display effect of the display panel is improved.

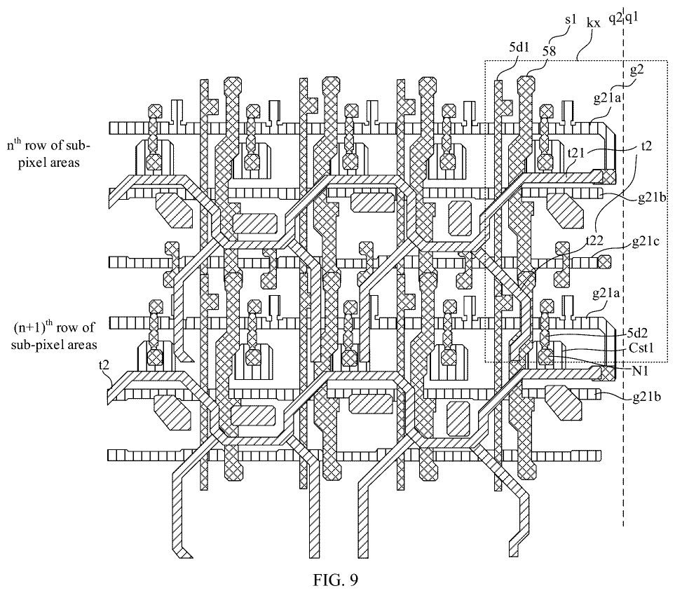

FIG. 9 is a layout of part of the structure in a display panel according to an embodiment of the present disclosure. Please refer to FIG. 9. The display panel includes a laminated gate line pattern g2 (the gate line pattern g2 may belong to the conventional signal lines), a source and drain metal pattern s1 and connection lines t2. The gate line pattern g2 includes gate lines disposed in the conventional display area q2, and the gate line pattern g2 may be connected with light-transmitting area gate lines (the light-transmitting area gate lines may belong to the light-transmitting area signal lines) in the light-transmitting display area q1 at a junction of the conventional display area q2 and the light-transmitting display area q1. In addition, the gate line pattern g2 may be connected with the connection lines t2 at the junction of the conventional display area q2 and the light-transmitting display area q1. The source and drain metal pattern s1 may include the N1 nodes. In FIG. 9, the structure of the same filling pattern is the same layer structure.

As can be seen from FIG. 9, the main line t21 of the connection line t2 in the n^{th} row of sub-pixel areas is disposed in the n^{th} row of sub-pixel areas, but the extension parts t22 in the connection line t2 extend into the (n+1)^{th} row of sub-pixel areas. In such a structure, the extension parts t22 are farther away from the N1 nodes in the n^{th} row of sub-pixel areas and do not affect the potential of the N1 nodes in the n^{th} row of sub-pixel areas, that is, the influence of an electric signal of the gate line in the n^{th} row of sub-pixel areas on the potential of the N1 nodes in the n^{th} row of sub-pixel areas is avoided, and the possibility of generating the annular mura problem nearby the FDC area is reduced.

In addition, in the embodiment of the present disclosure, the wiring pattern may be in the same layer structure as the source and drain metal pattern in the display panel. The display panel may include a plurality of layers of source and drain metal patterns, and the wiring pattern may be in the same layer structure as a second source and drain metal pattern in the display panel (the second source and drain metal pattern may be disposed above the source and drain metal pattern s1 in FIG. 9), or the wiring pattern may also be in the same layer structure as other structures in the display panel, which is not limited by the embodiment of the present disclosure.

In addition, the gate line pattern g2 in FIG. 9 may include gate lines g21a, gate lines g21b, and gate lines g21c. The gate lines g21a may be gate signal lines, the gate lines g21b may be emission control lines, and the gate lines g21c may be reset signal lines.

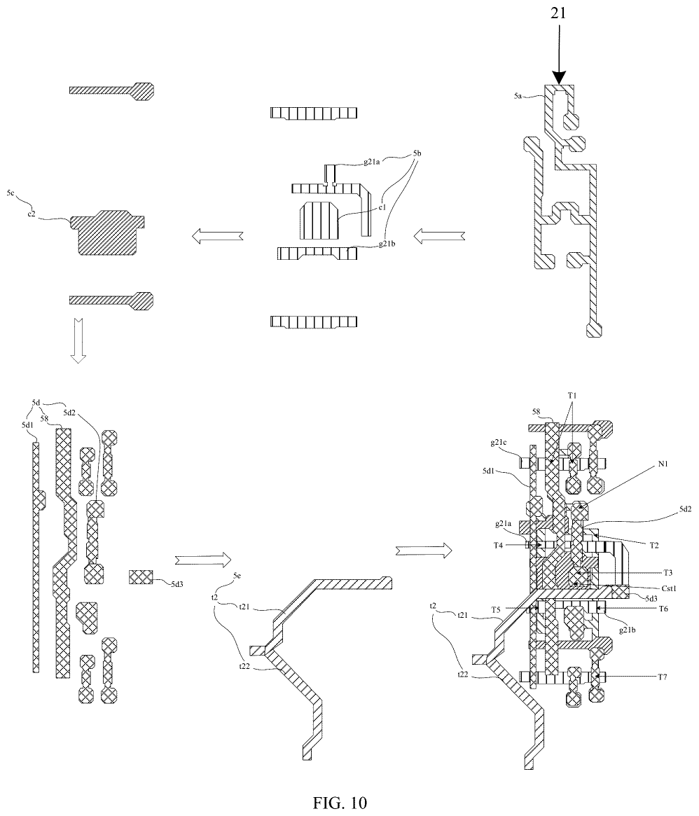

FIG. 10 is a disassembled and merged layout of part of the area in the display panel shown in FIG. 9 (FIG. 10 may be a layout of part of the structure in a dotted box kx in FIG. 9). Please refer to FIG. 9 and FIG. 10. The pixel driving circuit may include an active layer pattern 5a, a first conductive pattern 5b, a second conductive pattern 5c and a third conductive pattern 5d. The first conductive pattern 5b may include a first electrode plate c1 of the storage capacitor, the gate line g21a (which may be the gate signal line), the gate line g21b (which may be the emission control line) and the gate line g21c (which may be the reset signal line). The second conductive pattern 5c may include a second electrode plate c2 of a capacitive structure. The third conductive pattern 5d may include a data signal line 5d1, a power line 58, a node connection line 5d2, a source electrode and a drain electrode.

The gate line g21a may be connected with a connection structure 5d3 (the connection structure may belong to the source and drain metal layer) at the junction of the conventional display area q2 and the light-transmitting display area q1, and electrically connected with the connection line t2 through the connection structure 5d3. The main line t21 in the connection line t2 extends along the row direction, and the extension parts t22 extend downward into the next row of sub-pixel areas.

In addition, FIG. 10 also shows a plurality of thin film transistors (T1 to T7), and a circuit structure of these thin film transistors may refer to FIG. 8. In addition, in the embodiment of the present disclosure, T (upper case) 2 represents the second thin film transistor, and t (lower case) 2 represents the connection line in the winding structure.

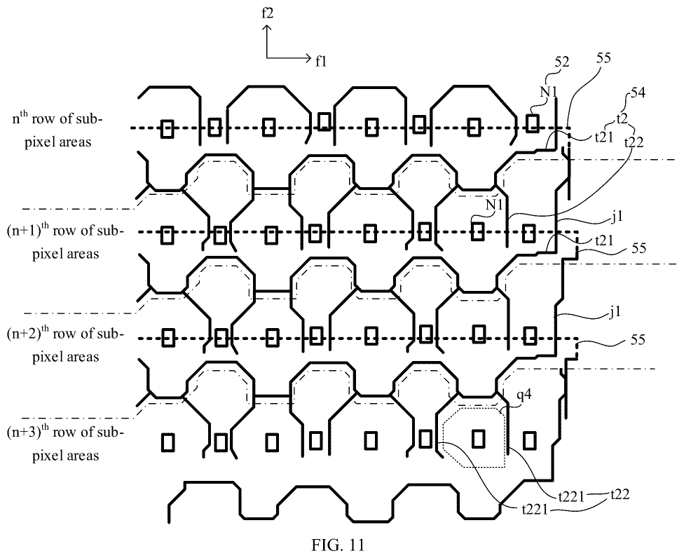

For the second mode, please refer to FIG. 11. FIG. 11 is a schematic structural diagram of another display panel according to an embodiment of the present disclosure. The conventional signal line 55 in the n^{th} row of sub-pixel areas is connected with the connection lines t2 of the winding structures corresponding to other rows of sub-pixel areas except the n^{th} row of sub-pixel areas in the plurality of rows of sub-pixel areas. In such a structure, when driving the light-emitting devices in the n^{th} row of sub-pixel areas, the extension parts t22 in the winding structure with which the n^{th} row of conventional signal line 55 is connected are disposed in other rows of sub-pixel areas and do not affect the pixel driving circuits in the n^{th} row of sub-pixel areas and because the pixel driving circuits in other rows of sub-pixel areas are not in the data writing state at this time, a voltage variation on the extension parts t22 has little influence on the pixel driving circuits in other rows of sub-pixel areas, thereby improving the display effect of the display panel, and reducing the possibility of generating the problem of uneven brightness.

In the embodiment of the present disclosure, a mode of dividing one row of sub-pixel areas may be as shown in FIG. 11, where a lower boundary of the n^{th} row of sub-pixel areas may be disposed below the main line t21 in the n^{th} row. In other display panels according to the embodiments of the present disclosure, the mode of dividing the sub-pixel areas may refer to FIG. 11, which will not be described in detail in the following embodiments of the present disclosure.

In an exemplary embodiment, the extension part t22 includes at least one sub-line segment t221, and the at least one sub-line segment t221 is arranged around an opening area q4. In the structure shown in FIG. 11, the number of the sub-line segments t221 is two, and the two sub-line segments t221 are respectively disposed on both sides of the opening area q4 in the row direction f1.

In an exemplary embodiment, the conventional signal line 55 in the n^{th} row of sub-pixel areas is connected with the connection line of the winding structure corresponding to the (n+x)^{th} row of sub-pixel areas in the plurality of rows of sub-pixel areas, and x is an integer greater than zero. FIG. 11 shows a case where the conventional signal line 55 in the n^{th} row of sub-pixel areas is connected with the connection line of the winding structure corresponding to the (n+1)^{th} row of sub-pixel areas in the plurality of rows of sub-pixel areas, but this is not limited by the embodiment of the present disclosure. Exemplarily, the conventional signal line 55 in the n^{th} row of sub-pixel areas may also be connected with the connection line of the winding structure corresponding to the (n+2)^{th} or the (n+3)^{th} row of sub-pixel areas in the plurality of rows of sub-pixel areas and so on.

The circuit structure also includes jumper lines j1. One end of the jumper line j1 is connected with the conventional signal line 55 in the n^{th} row of sub-pixel areas, and the other end of jumper line j1 is connected with the connection lines t2 of the winding structures corresponding to other rows of sub-pixel areas except the n^{th} row of sub-pixel areas. The jumper line j1 and the connection line t2 may be of the same layer structure.

It should be noted that in the display panel according to the embodiment of the present disclosure, the connection line t2 may be connected with the conventional signal line 55 through the source and drain metal pattern below.

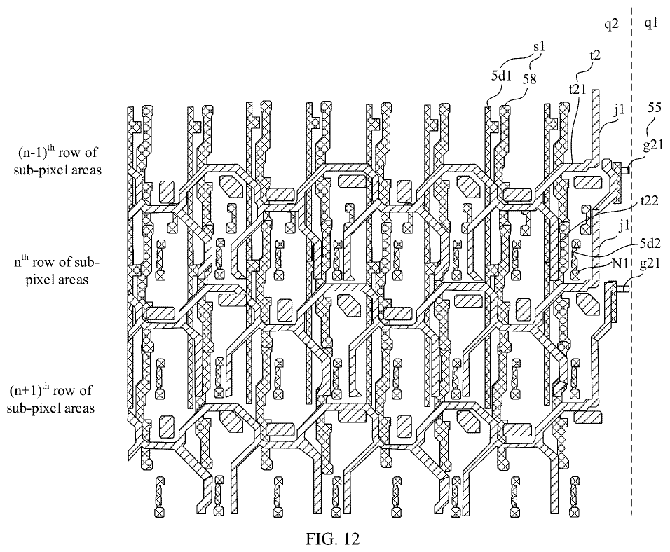

Please refer to FIG. 12, which is a layout corresponding to part of the structure of the display panel shown in FIG. 11, where the conventional gate line g21 in the n^{th} row of sub-pixel areas (the conventional gate line g21 is the gate line disposed in the conventional display area and belongs to the conventional signal line) is connected with the connection line t2 of the winding structure corresponding to the (n+1)^{th} row of sub-pixel areas in the plurality of rows of sub-pixel areas. In such a structure, when driving the light-emitting devices in the n^{th} row of sub-pixel areas, the extension parts in the wiring structure with which the conventional signal line 55 in the n^{th} row of sub-pixel areas is connected are disposed in the (n+1)^{th} row of sub-pixel areas and do not affect the pixel driving circuits in the n^{th} row of sub-pixel areas. Since the pixel driving circuits in other rows of sub-pixel areas are not in the data writing state at this time, a voltage change on the extension parts has little influence on the pixel driving circuits in other rows of sub-pixel areas, thereby improving the display effect of the display panel and reducing the possibility of generating the problem of uneven brightness. It should be noted that FIG. 12 only shows the connection point between the conventional gate line g21 and the main line t21 of the connection line, but does not limit the structure of the conventional gate line.

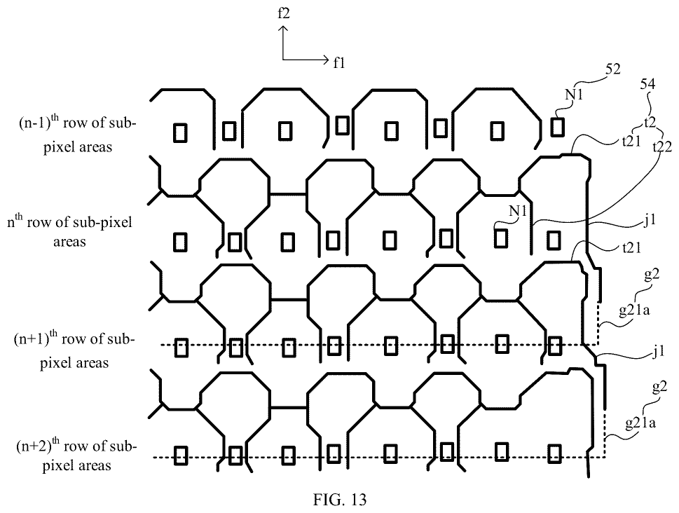

Another structure similar to the display panel shown in FIG. 11 may be as shown in FIG. 13, which is a schematic structural diagram of another display panel according to an embodiment of the present disclosure. The conventional signal line 55 in the n^{th} row of sub-pixel areas is connected with the connection line of the winding structure corresponding to the (n−x)^{th} row of sub-pixel areas in the plurality of rows of sub-pixel areas, and x is an integer greater than zero, for example, x may be 1, 2, 3, 4, 5, 6, 7, 8 or 9.

FIG. 13 shows a case where the conventional gate line g21a (the conventional gate line g21a belongs to the conventional signal line 551) in the (n+1)^{th} row of sub-pixel areas is connected with the connection line t2 of the winding structure corresponding to the (n−1)^{th} row of sub-pixel areas in the plurality of rows of sub-pixel areas, but this is not limited by the embodiment of the present disclosure. For example, the conventional gate line g21b in the (n+2)^{th} row of sub-pixel areas is connected with the connection line t2 of the winding structure corresponding to the n^{th} row of sub-pixel areas in the plurality of rows of sub-pixel areas. Exemplarily, the conventional signal line 551 in the n^{th} row of sub-pixel areas may also be connected with the connection line of the winding structure corresponding to the (n−2)^{th} or the (n−3)^{th} row of sub-pixel areas in the plurality of rows of sub-pixel areas and so on.

In such a structure, when driving the light-emitting devices in the n^{th} row of sub-pixel areas, the extension parts in the winding structure with which the conventional signal line 55 in the (n+1)^{th} row of sub-pixel areas is connected are disposed in the (n−1)^{th} row of sub-pixel areas and do not affect the pixel driving circuits in the n^{th} row of sub-pixel areas. Since the pixel driving circuits in other rows of sub-pixel areas are not in the data writing state at this time, a voltage change on the extension parts has little influence on the pixel driving circuits in other rows of sub-pixel areas, thereby improving the display effect of the display panel, and reducing the possibility of generating the problem of uneven brightness.

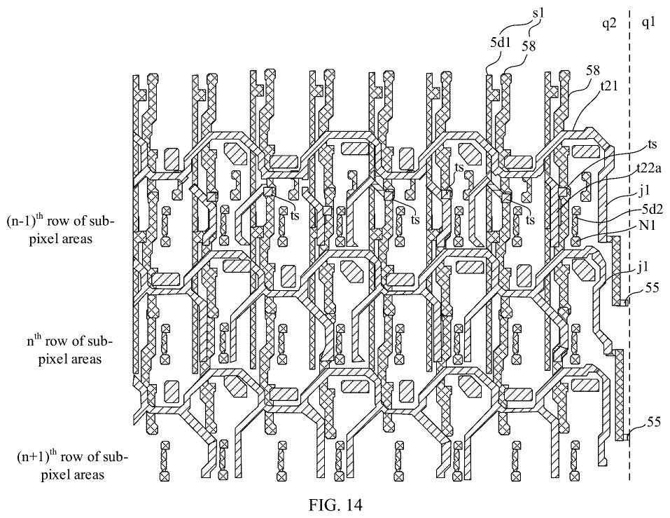

Please refer to FIG. 14, which is a layout corresponding to the display panel shown in FIG. 13, in which the conventional gate line g21a (the conventional gate line g21a belongs to the conventional signal line 551) in the (n+1)^{th} row of sub-pixel areas is connected with the connection line t2 of the winding structure corresponding to the (n−1)^{th} row of sub-pixel areas in the plurality of rows of sub-pixel areas. In such a structure, when driving the light-emitting devices in the n^{th} row of sub-pixel areas, the extension parts in the winding structure with which the conventional gate line g21a in the (n+1)^{th} row of sub-pixel areas is connected are disposed in the (n−1)^{th} row of sub-pixel areas and do not affect the pixel driving circuits in the (n+1)^{th} row of sub-pixel areas. Since the pixel driving circuits in other rows of sub-pixel areas are not in the data writing state at this time, a voltage change on the extension parts has little influence on the pixel driving circuits in other rows of sub-pixel areas, thereby improving the display effect of the display panel, and reducing the possibility of generating the problem of uneven brightness.

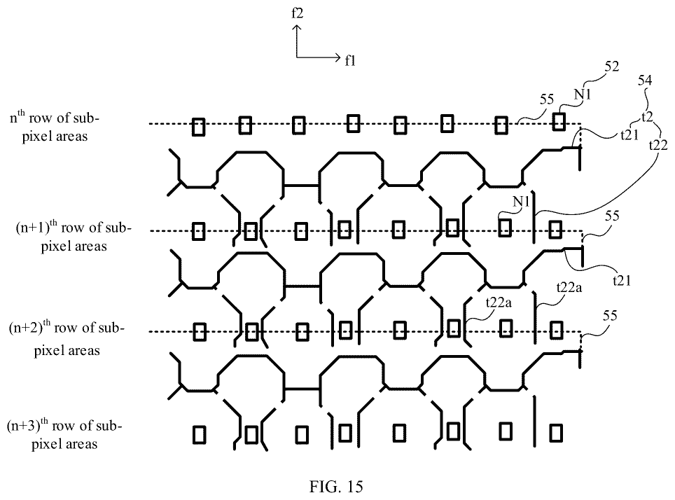

Exemplarily, as shown in FIG. 15, FIG. 15 is a schematic structural diagram of another display panel according to an embodiment of the present disclosure. In an exemplary embodiment, the plurality of extension parts t22 include at least one disconnected extension part t22a, and the disconnected extension part t22a is disconnected from the main line t21. In the display panels according to the above embodiments of the present disclosure, any display panel may include the disconnected extension part. In this display panel, the winding pattern includes a plurality of disconnected extension parts t22a, which are disconnected from the main lines t21. In such a structure, the disconnected extension part t22a does not access a signal, so that when the signal of the conventional signal line (such as the gate line) jumps, the disconnected extension part t22a is slightly affected, which further reduces the influence on the potential of the N1 node.

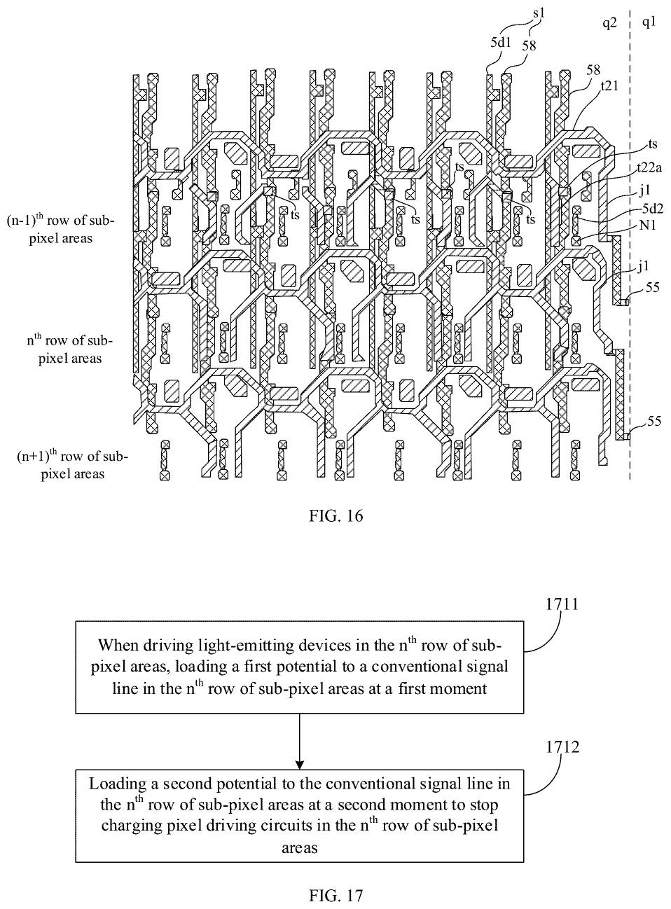

In addition, as shown in FIG. 16, which is a structural layout of another display panel according to an embodiment of the present disclosure, the display panel further includes a power line 58 (the power line 58 may be disposed in the source and drain metal pattern s1), and the at least one disconnected extension part t22a is electrically connected with the power line 58. There is a voltage stabilizing signal on the power line 58, and the disconnected extension part t22a is connected with the power line 58, which can prevent an island structure, i.e., the disconnected extension part t22a from generating a parasitic capacitance with the voltage change of other signal lines. The disconnected extension part t22a of FIG. 16 is connected with the power line 58 at the ts position.

It should be noted that FIG. 16 only shows a case where one row of sub-pixel areas have the disconnected extension part t22a, and this disconnected extension part t22a is connected with the power line 58. Other rows of sub-pixel areas may also have similar structures, which is not limited by the embodiment of the present disclosure.

In summary, for the display panel according to the embodiment of the present disclosure, the extension parts on the connection line with which the signal line in the n^{th} row of sub-pixel areas is connected extend to other rows of sub-pixel areas except the n^{th} row of sub-pixel areas. In such a structure, when the light-emitting devices in the n^{th} row of sub-pixel areas are driven, the extension parts in the winding structure with which the signal line in the n^{th} row of sub-pixel areas is connected are disposed in other rows of sub-pixel areas and do not affect the pixel driving circuits in the n^{th} row of sub-pixel areas and because the pixel driving circuits in other rows of sub-pixel areas are not in a data writing state at this time, a voltage change on the extension parts has little influence on the pixel driving circuits in other rows of sub-pixel areas, thereby improving a display effect of the display panel, and reducing the possibility of generating the problem of uneven brightness.

FIG. 17 is a method flowchart of a display method for a display panel according to an embodiment of the present disclosure. The method may be configured to control any display panel according to the above embodiment, and the method may include the following steps 1711 and 1712.
Step 1711: when driving the light-emitting devices in the n^{th} row of sub-pixel areas, a first potential is loaded to the conventional signal line in the n^{th} row of sub-pixel areas at a first moment.

In this way, the pixel driving circuits in the n^{th} row of sub-pixel areas may be charged, at least part of circuits of the pixel driving circuits in the sub-pixel areas where the extension parts are disposed jump to the first potential under the influence of the first potential and, and the sub-pixel areas where the extension parts are disposed are the sub-pixel areas except the n^{th} row of sub-pixel areas in the plurality of rows of sub-pixel areas in the display panel.
Step 1712: at a second moment, a second potential is loaded to the conventional signal line in the n^{th} row of sub-pixel areas to stop charging the pixel driving circuits in the n^{th} row of sub-pixel areas.

The conventional signal line may include a conventional gate line.

At least part of the circuits of the pixel driving circuits in the sub-pixel areas where the extension parts are disposed jump to the second potential under the influence of the second potential. One of the first potential and the second potential is a high potential, and the other potential is a low potential. Exemplarily, the first potential may be a low potential for opening a switch to start charging, and the second potential is a high potential for closing the switch to stop charging.

In the above driving process, the light-emitting devices in other rows of sub-pixel areas except the n^{th} row of sub-pixel areas are in a light-emitting state, but not in a charging state, the potential of the N1 nodes jumps to the first potential and then to the second potential in a very short time, and the two jumping processes cancel each other out, so that the brightness of the light-emitting devices in other rows of sub-pixel areas will not be affected basically. In this way, the possibility of annular mura nearby an FDC area is avoided, and the display effect of the display panel is improved.

In summary, for the display panel according to the embodiment of the present disclosure, the extension parts on the connection line with which the signal line in the n^{th} row of sub-pixel areas is connected extend to other rows of sub-pixel areas except the n^{th} row of sub-pixel areas, In such a structure, when the light-emitting devices in the n^{th} row of sub-pixel areas are driven, the extension parts in the winding structure connected with the signal line in the n^{th} row of sub-pixel areas are disposed in other rows of sub-pixel areas and do not affect the pixel driving circuits in the n^{th} row of sub-pixel areas and because the pixel driving circuits in other rows of sub-pixel areas are not in a data writing state at this time, a voltage change on the extension parts has little influence on the pixel driving circuits in other rows of sub-pixel areas, thereby improving a display effect of the display panel, and reducing the possibility of generating the problem of uneven brightness.

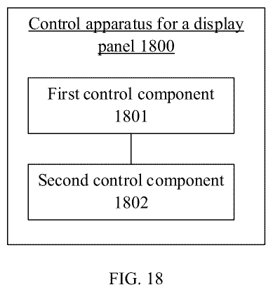

FIG. 18 is a block diagram of a control apparatus for a display panel according to an embodiment of the present disclosure, the control apparatus for a display panel may be configured to control any display panel according to the above embodiment, and the control apparatus for a display panel 1800 may include a first control component 1810 and a second control component 1820.

The first control component 1810 is configured to load a first potential to the conventional signal line in the n^{th} row of sub-pixel areas at a first moment, when driving the light-emitting devices in the n^{th} row of sub-pixel areas, so as to charge the pixel driving circuits in the n^{th} row of sub-pixel areas, and cause at least part of circuits of the pixel driving circuits in the sub-pixel areas where the extension parts are disposed to jump to the first potential under the influence of the first potential, the sub-pixel areas where the extension parts are disposed being the sub-pixel areas in the plurality of rows of sub-pixel areas in the display panel except the n^{th} row of sub-pixel areas; and
The second control component 1820 is configured to load a second potential to the conventional signal line in the n^{th} row of sub-pixel areas at a second moment, so as to stop charging the pixel driving circuits in the n^{th} row of sub-pixel areas and cause at least part of circuits of the pixel driving circuits in the sub-pixel areas where the extension parts are disposed to jump to the second potential under the influence of the second potential.

In summary, for the display panel according to the embodiment of the present disclosure, the extension parts on the connection line with which the signal line in the n^{th} row of sub-pixel areas is connected extend to other rows of sub-pixel areas except the n^{th} row of sub-pixel areas, In such a structure, when the light-emitting devices in the n^{th} row of sub-pixel areas are driven, the extension parts in the winding structure with which the signal line in the n^{th} row of sub-pixel areas is connected are disposed in other rows of sub-pixel areas, and do not affect the pixel driving circuits in the n^{th} row of sub-pixel areas and because the pixel driving circuits in other rows of sub-pixel areas are not in a data writing state at this time, a voltage change on the extension parts has little influence on the pixel driving circuits in other rows of sub-pixel areas, thereby improving a display effect of the display panel, and reducing the possibility of generating the problem of uneven brightness.

In addition, the embodiment of the present disclosure also provides a display apparatus. The display apparatus includes an optical device and the display panel according to the above embodiment. The optical device is disposed on a back surface of the display panel (the back surface of the display panel is a surface in the display panel opposite to a display surface), and there is an overlapping area between an orthographic projection on the display panel and the light-transmitting display area of the display panel.

The optical device may be configured to acquire light information in an environment right in front of the display panel through the light-transmitting display area of the display panel and emit light to the environment right in front of the display panel. The optical device may include a visible light camera, an infrared light camera, a dot matrix projector, etc., which is not limited by the embodiment of the present disclosure.

In addition, the embodiment of the present disclosure also provides a display device. The display device includes a processor, a memory and a display panel. At least one instruction, at least one program, a code set or an instruction set is stored in the memory, and the at least one instruction, the at least one program, the code set or the instruction set is loaded and executed by the processor to implement the display method for a display panel according to the above embodiment.

The embodiment of the present disclosure also provides a computer storage medium. The computer storage medium has at least one instruction, at least one program, a code set or an instruction set stored therein, and the at least one instruction, the at least one program, the code set or the instruction set is loaded and executed by a processor to implement the display method for a display panel according to the above embodiment.

It should be noted that in the accompanying drawings, for clarity of the illustration, the dimension of the layers and regions may be scaled up. It may be understood that when an element or layer is described as being “above” another element or layer, the described element or layer may be directly on the other element or layer, or an intermediate layer may exist. In addition, it may be understood that when an element or layer is described as being “below” another element or layer, the described element or layer may be directly below the other element or layer, or more than one intermediate layer or element may exist. In addition, it may be further understood that when a layer or element is described as being arranged “between” two layers or elements, the described layer or element may be the only layer between the two layers or elements, or more than one intermediate layer or element may exist. In the whole description above, like reference numerals denote like elements.

In the present disclosure, the terms “first”, “second”, “third” and “fourth” are configured for descriptive purposes only and are not to be construed as indicating or implying relative importance. The term “plurality” refers to two or more, unless specifically defined otherwise.

In the several embodiments according to the present disclosure, it should be understood that the disclosed apparatuses and methods may be implemented in other manners. For example, the apparatus embodiments described above are merely illustrative. For example, the division of the units is only logical function division. In actual implementation, there may exist other division manners. For example, multiple units or components may be combined or integrated into another system, or some features may be ignored or not executed. In addition, the mutual coupling or direct coupling or communication connection shown or discussed may be indirect coupling or communication connection by certain interfaces, apparatuses or units, or electrical connection, mechanical connection or the connection of other forms.

The units described as separate components may or may not be physically separate, and the components displayed as units may or may not be physical units, that is, may be disposed in one place, or may be distributed to multiple network units. Part or all of the units may be selected according to actual needs to achieve the objectives of the solutions of the embodiments of the present disclosure.

Those skilled in the art can understand that all or part of the steps of implementing the above embodiments may be completed by hardware, or may be completed by related hardware instructed by a program, and the program may be stored in a computer-readable storage medium. The storage medium mentioned above may be a read only memory, a magnetic disk or an optical disk or the like.

Described above are merely optional embodiments of the present disclosure, and are not intended to limit the present disclosure. Within the spirit and principles of the disclosure, any modifications, equivalent substitutions, improvements, and the like are within the protection scope of the present disclosure.

1. A display panel, comprising: a substrate having a light-transmitting display area and a conventional display area surrounding the light-transmitting display area thereon, wherein the light-transmitting display area and the conventional display area have a plurality of sub-pixel areas therein, the plurality of sub-pixel areas are arranged in a plurality of rows of sub-pixel areas on the substrate, and the plurality of sub-pixel areas have connected pixel driving circuits and light-emitting devices therein;
the conventional display area comprises a winding pattern and a plurality of conventional signal lines respectively disposed in the plurality of rows of sub-pixel areas, and the winding pattern and the plurality of conventional signal lines are disposed in different layers; and
the winding pattern comprises a plurality of connection lines respectively disposed in the plurality of rows of sub-pixel areas, each of the plurality of connection lines comprises a main line extending along a row direction of the sub-pixel area and a plurality of extension parts extending to adjacent sub-pixel areas, each of the plurality of connection lines is connected with each of the plurality of conventional signal lines, and the plurality of extension parts on each of the plurality of connection lines with which each of the plurality of conventional signal lines in an n^{th} row of sub-pixels is connected extend to other rows of sub-pixel areas except the n^{th} row of sub-pixels, wherein n is an integer greater than zero.

2. The display panel according to claim 1, wherein the display panel further comprises a pixel definition layer disposed on the substrate, the pixel definition layer comprises a shielding area and a plurality of opening areas, the plurality of opening areas are respectively disposed in the plurality of sub-pixel areas, and an orthographic projection of each of the plurality of extension parts on the substrate is disposed in an orthographic projection of the shielding area on the substrate; and
the plurality of extension parts comprise at least one disconnected extension part, and the disconnected extension part is disconnected from the main line.

3. The display panel according to claim 2, wherein each of the plurality of extension parts comprises at least one sub-line segment, and the at least one sub-line segment is arranged around the opening area.

4. The display panel according to claim 3, wherein each of the plurality of extension parts comprises two sub-segments respectively disposed on two sides of the opening area in the row direction.

5. The display panel according to claim 2, wherein the display panel further comprises a power line, and the at least one disconnected extension part is electrically connected with the power line.

6. The display panel according to claim 1, wherein the pixel driving circuit comprises a storage capacitor disposed in the sub-pixel area and a node connection line, the node connection line is connected with one end of the storage capacitor, and a capacitor connection has an N1 node;
a conventional signal line in the n^{th} row of sub-pixel areas is connected with a connection line of a winding structure corresponding to the n^{th} row of sub-pixel areas; and
a main line of the connection line of the winding structure corresponding to the n^{th} row of sub-pixel areas is disposed on a first side of the N1 nodes of the n^{th} row of sub-pixel areas, extension parts of the connection line of the winding structure corresponding to the n^{th} row of sub-pixel areas extend to an adjacent row of sub-pixel areas on a second side of the n^{th} row of sub-pixel areas, and the first side and the second side are both sides in a direction perpendicular to the row direction.

7. The display panel according to claim 1, wherein a conventional signal line in the n^{th} row of sub-pixel areas is connected with connection lines of the winding structures corresponding to other rows of sub-pixel areas except the n^{th} row of sub-pixel areas in the plurality of rows of sub-pixel areas.

8. The display panel according to claim 7, wherein the display panel further comprises a jumper line, one end of the jumper line is connected with the conventional signal line in the n^{th} row of sub-pixel areas, and the other end of the jumper line is connected with the connection lines of the winding structures corresponding to other rows of sub-pixel areas except the n^{th} row of sub-pixel areas.

9. The display panel according to claim 8, wherein the jumper line and the winding structure are of a same layer structure.

10. The display panel according to claim 7, wherein the conventional signal line in the n^{th} row of sub-pixel areas is connected with a connection line of a winding structure corresponding to an (n+x)^{th} row of sub-pixel areas in the plurality of rows of sub-pixel areas, and x is an integer greater than zero.

11. The display panel according to claim 7, wherein the conventional signal line in the n^{th} row of sub-pixel areas is connected with a connection line of a winding structure corresponding to an (n−x)^{th} row of sub-pixel areas in the plurality of rows of sub-pixel areas, and x is an integer greater than zero.

12. The display panel according to claim 1, wherein the winding pattern further comprises a plurality of surrounding lines extending around the light-transmitting display area, and an end part of each of the plurality of surrounding lines is connected with each of the plurality of connection lines.

13. The display panel according to claim 1, wherein the conventional signal line comprises a conventional gate line, and each of the plurality of connection lines is connected with the conventional gate line.

14. The display panel according to claim 1, wherein the display panel comprises a source and drain metal pattern, and the winding pattern and the source and drain metal pattern are of a same layer structure.

15. The display panel according to claim 1, wherein light-emitting devices in the light-transmitting display area are connected with the pixel driving circuits in one-to-one correspondence.

16. The display panel according to claim 1, wherein one pixel driving circuit in the light-transmitting display area is connected with at least two light-emitting devices.

17. The display panel according to claim 1, wherein a density of light-emitting devices in the light-transmitting display area is less than a density of light-emitting devices in the conventional display area.

18. A display panel, comprising: a light-transmitting display area and a conventional display area surrounding the light-transmitting display area; wherein
the light-transmitting display area and the conventional display area have a plurality of sub-pixel areas therein, the plurality of sub-pixel areas are arranged in a plurality of rows of sub-pixel areas, and the sub-pixel areas have connected pixel driving circuits and light-emitting devices therein;
the conventional display area comprises a winding pattern, the light-transmitting display area comprises a plurality of light-transmitting area signal lines, and the plurality of light-transmitting area signal lines and the winding pattern are disposed in different layers; and
the winding pattern comprises a plurality of winding structures respectively corresponding to the plurality of rows of sub-pixel areas, a winding structure corresponding to an n^{th} row of sub-pixel areas in the plurality of rows of sub-pixel areas comprises a surrounding line extending around the light-transmitting display area and a connection line disposed in the n^{th} row of sub-pixels, the connection line is connected with an end part of the surrounding line, the connection line comprises a main line extending along a row direction of the n^{th} row of sub-pixel areas and a plurality of extension parts extending to the sub-pixel areas, connection lines of the plurality of winding structures are respectively connected with the plurality of light-transmitting area signal lines, extension parts on a connection line with which the light-transmitting area signal line in the n^{th} row of sub-pixels is connected extend to other rows of sub-pixel areas except the n^{th} row of sub-pixels, and n is an integer greater than zero.

19. A display apparatus, comprising an optical device and the display panel according to claim 1, wherein the optical device is disposed on a back surface of the display panel, and there is an overlapping area between an orthogonal projection of the optical device on the display panel and the light-transmitting display area of the display panel.

20. A display method for a display panel, wherein the method is used for controlling the display panel according to claim 1 and comprises:
when driving the light-emitting devices in the n^{th} row of sub-pixel areas, loading a first potential to the conventional signal line in the n^{th} row of sub-pixel areas at a first moment, so as to charge the pixel driving circuits in the n^{th} row of sub-pixel areas, and cause at least part of circuits of the pixel driving circuits in sub-pixel areas where the extension parts are disposed to jump to the first potential under an influence of the first potential, the sub-pixel areas where the extension parts are disposed being sub-pixel areas in the plurality of rows of sub-pixel areas in the display panel except the n^{th} row of sub-pixel areas; and
loading a second potential to the conventional signal line in the n^{th} row of sub-pixel areas at a second moment, so as to stop charging the pixel driving circuits in the n^{th} row of sub-pixel areas, and cause at least part of circuits of the pixel driving circuits in the sub-pixel areas where the extension parts are disposed to jump to the second potential under the influence of the second potential.
